(19) United States
(12) Patent Application Publication
(10) Pub. No.: US 2010/0012964 A1
(43) Pub. Date: Jan. 21, 2010

(54) ILLUMINATION SYSTEM COMPRISING MONOLITHIC CERAMIC LUMINESCENCE CONVERTER

(75) Inventors: Roel Copic, Eindhoven (NL); Peter J. Schmidt, Aachen (DE); Arlis Gregory Van Braam, Eindhoven (NL); Andreas Tuecks, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/513,519

(22) PCT Filed: Oct. 30, 2007
(86) PCT No.: PCT/IB2007/054398

§ 371 Date: May 5, 2009

(30) Foreign Application Priority Data
Nov. 10, 2006 (EP) 06123825.9

(51) Int. Cl. H01L 33/00; C09K 11/00

(52) U.S. Cl. 257/98; 264/21; 257/E33.061

(57) ABSTRACT

An illumination system comprising a radiation source and a composite monolithic ceramic luminescence converter comprising a composite luminescent material comprising at least one first phosphor and at least one second phosphor capable of absorbing a part of the light emitted by the radiation source and emitting light of a wavelength different from that of the absorbed light provides improved light mixing and chromaticity control of the emitted light mixture. The invention relates also to a composite monolithic ceramic luminescence converter and a method of manufacturing such composite monolithic ceramic luminescence converter.

### FIELD OF THE INVENTION

The invention relates to an illumination system comprising a radiation source and a monolithic ceramic luminescence converter comprising at least one phosphor capable of absorbing part of the light emitted by the radiation source and emitting light of a wavelength different from that of the absorbed light. Preferably the radiation source is a light emitting diode.

### BACKGROUND TO THE INVENTION

It is known in the art that visible, white or colored light illumination can be provided by converting the color of light emitting diodes, emitting in the UV to blue range of the electromagnetic spectrum, by means of a luminescent material comprising a phosphor.

Such phosphor-converted “white” LED systems are based in particular on the dichromatic (BY) approach, i.e. mixing yellow and blue colors, in which case the yellow secondary component of the output light may be provided by a yellow phosphor and the blue component may be provided by a phosphor or by the primary emission of a blue LED.

White illumination systems may otherwise be based on the trichromatic (RGB) approach, i.e. on mixing three colors, namely red, green and blue, in which case the red and green component may be provided by a phosphor and the blue component by the primary emission of a blue-emitting LED.

As recent advances in light-emitting diode technology have brought very efficient light emitting diodes emitting in the near UV to blue range, today a variety of colored and white-light emitting phosphor-converted light emitting diodes are on the market, challenging traditional incandescent and fluorescent lighting.

The conventional phosphor converted light emitting device typically utilizes a design in which a semiconductor chip having a blue-emitting LED thereon is covered by a layer of epoxy resin containing phosphor particles powders of one or more phosphors.

In a more recent approach the semiconductor chip is covered by a layer of particles of one or more phosphors, which are deposited by an electrophoretic deposition technology (EPD). Such technology provides phosphor layers that are thinner than the resin-bonded phosphor layers. This allows for better chromaticity control and improved luminance.

However, a problem in prior art illumination systems comprising phosphor particle powders is that they cannot be used for many applications because they have a number of drawbacks:

Firstly, the deposition of a phosphor particle layer of uniform thickness is difficult. The phosphor particles tend to agglomerate, and hence, providing a uniform phosphor layer with particles of a known grain size is difficult. Since color uniformity requires a uniform layer thickness, color uniformity is difficult to guarantee.

Secondly, conventional phosphor particles are transferred into phosphor layers that backscatter a large part of the light emitted by the LED back into the chip, which is relatively absorptive, leading to a lower light-extraction efficiency.

WO2006/087660 discloses an illumination system comprising a radiation source and a monolithic ceramic luminescence converter comprising at least one phosphor capable of absorbing a part of the light emitted by the radiation source and emitting light of a wavelength different from that of the absorbed light, further comprising one or more second luminescence converter elements, wherein the second luminescence converter element is either a coating comprising a phosphor or wherein the second luminescence converter element is a second monolithic ceramic luminescence converter comprising a second phosphor.

Monolithic ceramic luminescence converters may be translucent or transparent. Therefore they do not impede the transmission of light and backscattering is minimal.

But regardless of where or how the luminescence converters disclosed in WO2006/087660 are arranged in the device, a majority of the first phosphor particles are positioned closer to the LED chip, and to receive incident light from the LED chip prior to the second phosphor particles. Therefore even these devices comprising monolithic ceramic luminescence converters vary in color-temperature across their surfaces.

It is therefore an object of the present invention to provide a phosphor-converted light-emitting diode with improved uniformity of the color of emitted light.

### SUMMARY OF THE INVENTION

Thus the present invention provides an illumination system comprising a radiation source and a composite monolithic ceramic luminescence converter comprising a composite luminescent material comprising at least one first phosphor and at least one second phosphor capable of absorbing part of the light emitted by the radiation source and emitting light of a wavelength different from that of the absorbed light.

The illumination system according to the invention will emit light that is a thorough mixture of the light emitted by the radiation source and light emitted by the composite monolithic luminescence converter comprising a plurality of phosphors. Therefore the emitted light has only variations in color, which are imperceptible to the human eye and only small and gradual variations in intensity.

According to an especially preferred embodiment of the invention the radiation source is a light emitting diode. Such illumination system is known as phosphor converted light emitting diodes (pcLED). As such, the composite monolithic ceramic luminescence converter greatly simplifies the manufacturing of various geometries of phosphor-converted light emitting diodes. Compared to conventional powder phosphor solutions the invention also shows the following advantages: higher package efficiency, higher luminance, pick and place assembly and improved color point control in pcLEDs.

According to one variant of the invention the composite luminescent material is a particle-particle composite. The composite monolithic ceramic luminescence converter comprising a particle-particle composite can be formed as a compact unitary element with a homogeneous spatial distribution of the plurality of phosphor materials. As the white point and color rendering of a phosphor-converted light emitting diode (pcLED) are extremely sensitive to the spatial distribution of the phosphor grains in the device chromaticity control is significantly improved. Consequently, the reject rate of such pcLEDs is very low, because the proper mixture of the phosphors is easy to control.

According to another variant of the invention the composite luminescent material is a stacked multilayer composite. The composite includes at least first and second component layers, which are repeating. In cases where joint ceramic processing of different phosphor materials is not possible, a stacked multilayer composite is a useful alternative to a particle-particle composite.

An especially preferred embodiment of the invention is a composite monolithic ceramic luminescence converter, wherein the first ceramic grains are formed by a green emitting phosphor material and the second ceramic grains are formed by a red emitting phosphor material. This embodiment is especially useful, if the first phosphor is a green-emitting europium(II)-doped alkaline earth oxonitridosilicate phosphor of general formula AeSi₂N₂O₂:Eu and the second phosphor is a red-emitting europium(II)-doped alkaline earth nitridosilicate phosphor of general formula Ae₂Si₅N₈:Eu, as there is an easy way of manufacturing of such ceramic luminescence converter disclosed. In combination with a blue-emitting diode the emitted light will be white light.

Another useful alternative is a composite monolithic ceramic luminescence converter, wherein the first phosphor is a yellow-emitting phosphor and the second phosphor is a blue-emitting phosphor. In combination with an UV-emitting diode the emitted light will also be white light.

The invention is also concerned with a composite monolithic ceramic luminescence converter comprising composite luminescent material comprising at least one first phosphor and at least one second phosphor capable of absorbing a part of the light emitted by the radiation source and emitting light of a wavelength different from that of the absorbed light. The composite monolithic ceramic luminescence converter eliminates the need for a discrete arrangement for each one of the phosphor materials, and provides for greatly enhanced light mixing characteristics. The composite monolithic, ceramic luminescence converter is easily machined to a uniform thickness, so the color conversion effect is the same across the surface, providing a more uniform composite light than the prior art devices.

As known to the experts, LED manufacture is plagued with optical variability and imprecise process control. LED manufacturers currently deal with the process variability by ‘binning’ LED dies by any number of measured optical output properties such as, for example, wavelength and/or luminous intensity, and then re-binning the final phosphor converted LEDs by any number of measured optical output properties such as, for example, CIE x and y color coordinates, correlated color temperature (CCT) and/or radiant flux.

It is an advantage of the present invention, that the composite monolithic luminescence converters may be binned separately, i.e., grouped and stored, according to their light conversion properties. By grouping and storing the CLCs based on their light conversion properties, the manufacturing of phosphor converted LEDs can be greatly simplified, as a luminescence converting element having a desired light conversion property can be easily located and matched with a LED die to produce a desired result.

According to another aspect of the invention a method of manufacturing a composite monolithic ceramic luminescence converter comprising a composite luminescent material comprising at least one first phosphor and at least one second phosphor capable of absorbing a part of the light emitted by the radiation source and emitting light of a wavelength different from that of the absorbed light is provided, by (i) preparing a powder mixture by mixing a precursor of a first phosphor material with a second material, that is selected from the group of a second phosphor material and a precursor of the second phosphor material, (ii) compacting and shaping the powder mixture into a preform, and (iii) co-sintering the preformed mixture.

The process of co-sintering the preform ceramic elements provides improved dimensional control during sintering and reduces processing costs.

In one useful variant of the method according to the invention the precursor material is a green (non-sintered) ceramic phosphor powder. By this method the first and second phosphor materials are combined and consolidated to form a solid composite material in a way, which ensures that chemical reactions between the first and second phosphor are suppressed.

According to an especially preferred embodiment of this variant of the method according to the invention the first phosphor is a green-emitting europium(II)-doped alkaline earth oxonitridosilicate phosphor of general formula AeSi₂N₂O₂:Eu and the second phosphor is a red-emitting europium(II)-doped alkaline earth nitridosilicate phosphor of general formula Ae₂Si₅N₈:Eu, wherein the precursor of the first phosphor and the precursor of the second phosphor comprise a mixed oxide of an alkaline earth metal and europium, AeO:Eu, and silicon nitride Si₃N₄.

These and other objects, features and advantages will be apparent from the following detailed description, brief description of the drawings and appended claims and drawings.

### DETAILED DESCRIPTION OF THE INVENTION

The present invention focuses on a composite monolithic ceramic luminescence converter (CLC) comprising a luminescent material comprising a plurality of phosphors, at least one first and at least one a second phosphor in any configuration of an illumination system comprising a source of primary radiation. As used herein, the term “radiation” encompasses radiation in the UV, IR and visible regions of the electromagnetic spectrum.

In general, a ceramic luminescence converter is a ceramic, which emits electromagnetic radiation in the visible or near visible spectrum when stimulated by high-energy electromagnetic photons.

A monolithic ceramic luminescence converter is a ceramic body that is characterized by its typical microstructure. The microstructure of a monolithic ceramic luminescence converter is polycrystalline, i.e. an irregular conglomerate of cryptocrystalline, microcrystalline or nanocrystalline crystallites. During production crystallites are grown so as to come into close contact and share grain boundaries. Macroscopically the monolithic ceramic seems to be isotropic; however the polycrystalline microstructure can be easily detected by SEM (scanning electron microscopy).

Due to their monolithic polycrystalline microstructure, monolithic ceramic luminescence converters are transparent or have at least high optical translucency with low light absorption.

The monolithic ceramic luminescence converter according to the invention comprises at least one first and at least one a second phosphor (or three or four) in a composite arrangement, which each have their own emission characteristics.

The invention is operative with a variety of phosphor materials. The phosphor materials are typically inorganic in composition, having preferably excitation wavelengths in the blue to near UV range of the electromagnetic spectrum (300-475 nm) and emission wavelengths in the visible wavelength range. A composite of a plurality of phosphor materials is formulated to achieve the desired color balance, as perceived by the viewer, for example a mixture of red- and green-emitting phosphors or blue- and yellow-emitting phosphors. Phosphor materials having broader emission bands are useful for phosphor composites having higher color rendition indices. Such phosphors that convert light in the range of about 300 to 475 nm to longer wavelengths in the visible range are well known in the art.

With regard to the preparation of composite ceramic luminescence converters it is a particularly important aspect, that the plurality of phosphor materials are combined and consolidated to form the composite material in a manner that ensures that the microstructure of the solid monolithic composite is characterized by phosphor grains which maintain their respective luminescent properties.

To achieve this aspect, the individual constituent materials must essentially not react with one another in order to preserve their distinct crystalline phases because any interaction would significantly diminish the desired luminescent properties.

In a first variant of a method of manufacturing a composite monolithic ceramic luminescence converter comprising a plurality of phosphors in a composite arrangement the components of the composite luminescent material are provided in a particle-particle-composite arrangement.

Such particle-particle composite was prepared according to two methods. Each method entailed preparing (i) a powder mixture of a precursor of a first phosphor material with a second material that is selected from the group of a second phosphor material and a precursor of the second phosphor material, ((ii) powder compacting and shaping the mixture into a preform, and (iii) co-sintering the preformed mixture.

As evident, the relative quantities of the first and second phosphor materials can be chosen to affect the final properties of the composite and may vary widely, depending on the desired application.

In a first method the particle-particle composite is manufactured by mixing particles of at least one precursor material of a first phosphor with a second phosphor material.

In one embodiment of the first method the precursor of the first phosphor material is provided as a “green” ceramic material. “Green” in this context refers to a fired, but not yet sintered ceramic material.

A “green” ceramic material has a density less than theoretical density, typically less than 65% of theoretical density. It also has typically a grain size in the range from 0.1 to 10 μm.

This “green” precursor material of the first phosphor material is combined with a second phosphor material of a pre-sintered coarse grain size (particle size of about 1.0 to 50 micron). The first phosphor material is preferably the one with the lower sintering temperature in comparison to the second phosphor. Separated sintering of the phosphors helps to preserve the phase constituent separation and thus reduces the likelihood of an interaction between the constituents.

The two materials are mixed using standard ball milling techniques, though other methods known in the art could also be used with suitable results.

Once sufficiently mixed, the mixture is shaped into a preform. The solid composite preform should exhibit sufficient strength and toughness to resist chipping and cracking, as well as permit preshaping.

The preform is then sintered under the sintering conditions with regard to temperature and atmosphere that apply for sintering of the first phosphor material. Sintering treatment is provided for a desired amount of time to density the ceramic to substantially its theoretical density so as to form a transparent material. These parameters assure a minimum porosity and maximum density without interaction of the constituent phosphor materials.

Especially preferred is a hot isostatic pressure treatment, or otherwise a cold isostatic pressure treatment followed by sintering. A combination of cold isostatic pressing and sintering followed by hot isostatic pressing may also be applied.

Careful supervision of the densification process is necessary to control grain growth and to remove residual pores.

A composite monolithic ceramic luminescence converter is formed by heating the first doped powder phosphor and the second doped powder phosphor at high temperature until the surface of the particles begin to form a strong bond or neck at the contact points of the particles. During sintering, the partially connected particles form a rigid agglomerate that further decreases its porosity by further neck growth. Grain boundaries are formed and move so that some grains grow at the expense of others. This stage continues while the pore channels are connected (open porosity) until the pores are isolated (closed porosity). In the last sintering stage, the pores become closed and are slowly eliminated along grain boundaries until full densification is achieved.

Shaping and sintering treatment of the phosphor material results in a composite monolithic ceramic body, which is easily sawed and machined by current ceramic procedures. Preferably, the composite monolithic ceramic luminescence converter is polished to get a smooth surface and to impede diffuse scattering caused by surface roughness.

Particularly advantageous effects in comparison with the prior art are obtained using a monolithic ceramic luminescence converter in accordance with the invention having a particle-particle composite, where the surface of the particles of a coarse grain red-emitting phosphor is covered with a layer of fine-grain particles of a green phosphor. In this luminescent composite material the light mixing is particularly improved.

According to this specific embodiment, the composite ceramic luminescence converter has a composition consisting essentially of 70 to 90 wt-% green-emitting SrSi₂O₂N₂:Eu as a first phosphor material and 10 and 30 wt-% of red-emitting (Ba,Sr)₂Si₅N₈:Eu as a second phosphor material.

The preparation of the precursor material of a first green-emitting phosphor material SrSi₂O₂N₂:Eu starts with preparation of the mixed oxides of the divalent metals strontium and europium SrO:Eu.

To prepare the mixed oxides SrO:Eu of the divalent metals, high purity nitrates, carbonates, oxalates and acetates of the alkaline earth metals and europium(III) were dissolved by stirring in 25-30 ml of deionized water. A desirable concentration of europium(III) is between about 1 and 6 mole percent.

The solutions are stirred while being heated on a hotplate until the water has evaporated, resulting in a white or yellow paste, depending on the composition.

The solids are dried overnight (12 hours) at 120° C. The resulting solid is finely ground and placed into a high-purity alumina crucible. The crucibles are loaded into a charcoal-containing basin and subsequently into a tube furnace, after which they are purged with flowing nitrogen/hydrogen for several hours. The furnace parameters are 10° C./mm to 1100° C., followed by a 4-hour dwell at 1100° C., after which the furnace is turned off and allowed to cool to room temperature.

The divalent mixed metal oxides are then mixed with silicon nitride Si₃N₄, silicon oxide SiO₂ and eventually a flux in predetermined ratios.

The mixture is placed into a high-purity alumina crucible. The crucibles are loaded into a charcoal-containing basin and, subsequently, into a tube furnace and purged with flowing nitrogen/hydrogen for several hours. The furnace parameters are 10° C./mm to 1200° C., followed by a 4-hour dwell at 1200° C., after which the furnace is slowly cooled to room temperature.

The samples are once again finely ground before a second annealing step at 1300° C. is performed to prepare the “green” non-sintered ultrafine precursor material for green-emitting SrSi₂O₂N₂:Eu.

The preparation of a coarse grain, pre-sintered second powder material of red-emitting (Ba,Sr)₂Si₅N₈ Eu starts also with the preparation of the mixed oxides of the divalent metals (Sr,Ba)O:Eu.

The divalent metal oxides (Sr,Ba)O:Eu are mixed with silicon nitride Si₃N₄ and carbon in predetermined ratios. The mixture is placed into a high purity silicon carbide crucible. The crucibles are loaded into a charcoal-containing basin and then into a tube furnace and purged with flowing nitrogen/hydrogen for several hours. The furnace parameters are 10° C./min to 1450° C., followed by a 4 hour dwell at 1450° C. after which the furnace is slowly cooled to room temperature. The samples are once again finely ground before a second annealing step at 1500° C. is performed. The sintered coarse grain ceramic powder of (Ba,Sr)₂Si₅N₈:Eu has an average grain size of 2 to 8 μm.

To prepare the composite monolithic CLC, the ultrafine submicron precursor material of the first phosphor material and the coarse-grained sintered second phosphor material are mixed by wet milling.

The powder mixture is then air-dried at about 100° C. The mixture is uniaxially pressed into ceramic disks and then further compacted by means of cold isostatic pressing (3.2 kbar). The preform bodies are sintered in an H₂/N₂ (5/95) atmosphere for 2-12 hrs at 1550° C.

Generally sintering is performed in a reducing atmosphere. A nitrogen atmosphere, a nitrogen-hydrogen atmosphere, an ammonia atmosphere, and an inert gas atmosphere such as argon can be given as examples of the reducing atmosphere.

After cooling down to room temperature the composite monolithic ceramics obtained were sawed into disks. These disks were grinded and polished to obtain the final translucent composite monolithic ceramic luminescence converter comprising green-emitting SrSi₂O₂N₂:Eu and red-emitting (Ba,Sr)₂Si₅N₈ Eu phosphors grains in the ceramic matrix. The translucent composite monolithic ceramic luminescence converter may also contain a small amount of ceramic grains formed by (Ba,Sr,Eu)Si₇N₁₀ material that do not negatively affect the luminescence properties of the composite material.

The CLC microstructure of this special embodiment features a statistical granular structure of crystallites forming a grain boundary network at a magnification of 1000:1. The ceramics exhibit a density of at least 97% of the theoretical density. The density of the samples could further be improved by post-annealing of the ceramics in a nitrogen atmosphere (temperature range: 1500-1780° C., pressure range: 2000 to 30000 PSI (138 to 2.070 bar) to remove remaining porosity.

Using the above processing method, the phosphor materials are able to retain their luminescent properties. This result is highly unexpected, in that some reduction in the respective properties would be expected when co-sintering materials to form a composite. However, no significant loss in luminescent properties occurs.

In a second method of manufacturing a composite monolithic ceramic luminescence converter comprising a particle-particle composite precursor materials of a first and precursor material of a second phosphor are mixed for further processing.

This second method for preparing a composite ceramic luminescent converter according to the invention is useful, where the first and the second phosphor are of related chemical composition and precursors of the first and second phosphor can be reacted together.

Example given, the red phosphors comprising europium(II) in a alkaline earth nitridosilicate host matrix and green phosphors comprising europium(II) in a closely related alkaline earth oxonitridosilicate host matrix of the first embodiment described above can be prepared together by reacting silicon nitride with strontium oxide and/or another alkaline earth metal oxide selected from the oxides of magnesium, calcium, strontium and barium, according to equation:

4AeO:Eu+3Si₃N₄→Ae₂Si₅N₈:Eu+2AeSi₂O₂N₂:Eu

The starting powder for such a composition can be made by forming a mixture of precursor components of both phosphors in appropriate quantities. By appropriate quantities is meant relative concentrations, which result in the final transparent body containing the desired relative proportions of cations.

For a one step synthesis of a SrSi₂O₂N₂:Eu/Sr₂Si₅N₈:Eu composite SrO:Eu(2%) is mixed with Si₃N₄ in a dry atmosphere with a molar ratio SrO:Eu: Si₃N₄=1.5:1 and fired at 1550° C. in a stream of H₂/N₂ (5/95) for 4 hrs. The resulting powder is then hot pressed in a boron nitride coated graphite die at 100 Mpa, 1550° C. for two hours in vacuum. After hot pressing the ceramics are post-annealed under nitrogen at T=1200-1400° C.

A sintering treatment under such conditions causes a reaction between the solid precursor phases to produce a crystalline agglomerate of the two different phosphors Sr₂Si₅N₈:Eu and SrSi₂O₂N₂:Eu in a composite arrangement.

Apart from said particle-particle composite, the components of the luminescent material may also form a laminated composite in a multilayer arrangement.

In the laminated composite, the first layer comprises phosphor particles of a first phosphor material and the second layer comprises phosphor particles of a second phosphor material.

Tape casting using the doctor blade technique is widely used on the production of ceramic laminated multilayer composites. In this process a suspension of the ceramic phosphor powder in a liquid system composed of solvents, binders, and plasticizers is cast onto a moving carrier surface. The slurry passes beneath the knife of a blade that “doctors” the slurry into a layer of controlled thickness and width as the carrier surface advances along a supporting table. When the solvents evaporate, the ceramic particle coalescence into a relatively dense, flexible film that can be stripped from the carrier in a continuous sheet. The sheet is the cut into size, stacked alternatively with sheets of the second material in the proper sequence and laminated to form a solid, composite laminate. The laminate is fired to decompose and remove the organic binder and to sinter the phosphor particles, thus forming a dense composite monolithic CLC.

In addition to their structural homogeneity and integrity, the laminated multilayer composites of the invention offer physical properties, which are closely controllable over a very broad range of permissible values. Hence, the properties of the ultimate products depend simply upon the compositions, thicknesses, and properties of the foils selected for incorporation therein

In certain embodiments of the invention it may be useful to post-shape the sintered composite monolithic CLC, which can be done using routine procedures well known for ceramic materials. E.g. roughening the top surface of the composite monolithic CLC may be useful to scatter the converted light to improve light outcoupling, particularly, e.g., when the CLC has a high index of refraction.

According to a second aspect of the invention an illumination system comprising a radiation source and a composite monolithic ceramic luminescence converter comprising a composite luminescent material comprising at least one first phosphor and at least one second phosphor capable of absorbing a part of the light emitted by the radiation source and emitting light of a wavelength different from that of the absorbed light is provided.

Radiation sources include preferably semiconductor optical radiation emitters and other devices that emit optical radiation in response to electrical excitation. Semiconductor optical radiation emitters include light emitting diode LED chips, light emitting polymers (LEPs), laser diodes (LDs), organic light emitting devices (OLEDs), polymer light emitting devices (PLEDs), etc. Moreover radiation-emitting sources such as those found in discharge lamps and fluorescent lamps, such as mercury low and high-pressure discharge lamps, sulfur discharge lamps, and discharge lamps based on molecular radiators as well as in X-ray tubes are also contemplated for use as radiation sources with the present inventive luminescence converter.

In a preferred embodiment of the invention the radiation source is a light-emitting diode.

Any configuration of an illumination system, which includes a light-emitting diode, or an array of light-emitting diodes and a composite monolithic ceramic luminescence converter comprising a plurality of phosphors is contemplated in the present invention, to achieve a specific colored or white light when irradiated by a LED emitting primary UV or blue light as specified above.

Possible configurations useful to couple the composite monolithic ceramic luminescence converter to a light emitting diode or an array of light emitting diodes comprise epitaxy-up devices as well as flip chip devices.

A detailed construction of one embodiment of such an illumination system comprising a radiation source and a composite monolithic ceramic luminescence converter will now be described.

FIG. 1 schematically illustrates a specific structure of a solid-state illumination system 1 comprising a composite monolithic ceramic luminescence converter 2, wherein the LED die 4 is packaged in a flip chip configuration on a substrate 6, with both electrodes 5 contacting the respective leads without using bond wires. The LED die is flipped upside down and bonded onto a thermally conducting substrate. The monolithic ceramic luminescence converter is configured as a disk, which is positioned in such a way that most of the light, which is emitted from the light-emitting diode, enters the disk at an angle which is approximately perpendicular to the surface of the disk. To achieve this, a reflector 3 is provided around the light-emitting diode in order to reflect light that is emitted from the light-emitting diode in directions toward the disk.

Although FIG. 1 illustrate a particular LED structure, the present invention is independent of any particular structure of the LED die. For example, the number of substrates and semiconductor layers in LED die and the detailed structure of active region may be varied. Additionally, LED die is illustrated in FIG. 1 as having a “flip-chip” type architecture, i.e., the electrodes 5 are located on the same side of the LED die 1. If desired, however, other types of LED die architecture may be used with the present invention, such as having the electrodes 5 on opposite sides of the die.

The luminescence converter may be fixed to the LED die 2, e.g., by placing a transparent bonding layer 7 of a high temperature optically transparent resin material, such as epoxy, silicone or the like, between the luminescence converter and the LED die. When cured, the bonding layer 7 holds the luminescence converter to the LED die.

Otherwise low softening point glass is useful when bonding the composite monolithic ceramic luminescence converter directly to either the LED die. The materials may be bonded, by elevating the temperature of the LED die and the composite monolithic CLC above the softening point of the glass, and applying a pressure to press the materials together.

In operation, electrical power is supplied to the die to activate the die. When activated, the die emits the primary light, e.g. blue light. A portion of the emitted primary light is completely or partially absorbed by the ceramic luminescence converter. The ceramic luminescence converter then emits secondary light, i.e., the converted light having a longer peak wavelength, in response to absorption of the primary light. The remaining unabsorbed portion of the emitted primary light is transmitted through the ceramic luminescence converter, along with the secondary light.

The reflector directs the unabsorbed primary light and the secondary light in a general direction as output light. Thus, the output light is a composite light that is composed of the primary light emitted from the die and the secondary light emitted from the fluorescent layer.

The color temperature or color point of the output light of an illumination system according to the invention will vary depending upon the spectral distributions and intensities of the secondary light in comparison to the primary light.

Firstly, the color temperature or color point of the primary light can be varied by a suitable choice of the light emitting diode.

Secondly, the color temperature or color point of the secondary light can be varied by a suitable choice of the phosphor compositions in the composite monolithic ceramic luminescence converter.

Also the thickness and the relative phosphor contents in the composite may be configured to convert a desired percentage of primary light that is incident on the composite monolithic CLC.

Depending on the light-emission wavelength of the light emitting diode and the phosphors light emission of an arbitrary point in the chromaticity diagram in the color triangle (polygon) formed by the color points of the two (plurality of) phosphors and of the light emitting element can be provided.

According to one aspect of the invention the output light of the illumination system may have a spectral distribution such that it appears to be “white” light.

The term “white light” refers to light that stimulates the red, green, and blue sensors in the human eye to yield an appearance that an ordinary observer would consider “white”. Such light may be biased to the red (commonly referred to as warm white light) or to the blue (commonly referred to as cool white light). Such light can have a color-rendering index of up to 100. Particularly preferable is a white range light that has a chromaticity located on the blackbody line in the chromaticity diagram.

In a first embodiment of a white light emitting illumination system according to the invention the device can advantageously be produced by choosing the luminescent material such that a blue radiation emitted by a blue light emitting diode is converted into complementary red and green wavelength ranges, to form warm white light.

In this embodiment, the diode is selected from a blue emitting diode or a violet emitting diode, the first type of phosphor particles is capable of emitting red light upon excitation by the light from the diode, and the second type of phosphor particles is capable of emitting green light upon excitation by the light from the diode. In such an embodiment, the light emitting device thus emits light having a plurality of wavelength components, due to (a) light emitted from the diode that passes (unabsorbed) through the phosphor layer, (b) red light resulting from down-conversion of phosphor-absorbed, diode-emitted light, and (c) green light resulting from down-conversion of phosphor-absorbed, diode-emitted light. The result is a light-emitting device that emits white light.

In an preferred embodiment of the invention green and red light is produced by means of the phosphor materials of the composite monolithic ceramic luminescence converter, that comprises a red emitting (590-650 nm) phosphor of general formula Ae₂Si₅N₈:Eu, a green-emitting (500-560 nm) phosphor of general formula AeSi₂N₂O₂:Eu, wherein Ae is at least one earth alkaline metal chosen from the group of calcium, barium and strontium.

Particularly good results are achieved with a blue LED whose emission maximum lies at 380 to 480 nm. An optimum has been found to lie at 445 to 468 nm, taking particular account of the excitation spectrum of the europium(II)-activated phosphors.

A white-light emitting illumination system according to the invention can particularly preferably be realized by mounting a polished composite monolithic ceramic luminescence converter according to the invention with dimensions of 1.0×1.0×0.1 mm on an 1 W (Al,In,Ga)N LED chip emitting at 458 nm.

FIG. 2 shows the emission spectrum of pcLED with a composite monolithic ceramic luminescence converter comprising Sr₂Si₅N₈:Eu and Sr₂Si₂N₂O₂:Eu in combination with a blue-emitting LED having maximum emission at 460 nm. The correlated color temperature CCT was measured as 4200K, the color rendering index as Ra=80-92(R9<60).

The associated color point has the coordinates x=0.377 and y=0.392.

When compared with the spectral distribution of the white output light generated by the prior art illumination system comprising YAG:Ce the apparent difference in the spectral distribution is the shift of the peak wavelength which is in the red region of the visible spectrum. Thus, the white output light generated by the illumination system has a significant additional amount of red color, as compared to the output light generated by the prior art.

In another embodiment, the phosphor composition includes three different types of phosphor particles (a first type of phosphor particles, a second type of phosphor particles, and a third type of phosphor particles). In one embodiment, the diode is a UV diode, the first type of phosphor particles is capable of emitting red light upon excitation, the second type of phosphor particles is capable of emitting green light upon excitation, and the third type of phosphor particles is capable of emitting blue light upon excitation. In such an embodiment, the light emitting device thus emits light having a plurality of wavelength components, due to (a) UV light that passes (unabsorbed) through the ceramic luminescence converter, (b) red light resulting from down-conversion of phosphor-absorbed light, (c) green light resulting from down-conversion of phosphor-absorbed light, and (d) blue light resulting from down-conversion of phosphor-absorbed light. The result is a light-emitting device that emits white light.

In still another embodiment of a white light-emitting device, the device comprises a UV diode and a phosphor composition including two different types of phosphor particles (a first type of phosphor particles and a second type of phosphor particles). In one such embodiment, the first type of phosphor particles is capable of emitting yellow light upon excitation, and the second type of phosphor particles is capable of emitting blue light upon excitation. In such an embodiment, the light emitting device thus emits light having a plurality of wavelength components, due to (a) UV light that passes (unabsorbed) through the luminescence converter, (b) yellow light resulting from down-conversion of phosphor-absorbed light, and (c) blue light resulting from down-conversion of phosphor-absorbed light. The result is a light-emitting device that emits white light.

According to alternative embodiment of the invention an illumination system that emits output light having a spectral distribution such that it appears to be colored, e.g. “yellow to red” is provided.

Besides of the phosphors of the special embodiments described above, typical phosphor particles suitable for use in the phosphor composition comprise a material selected from SrS:Eu²⁺; CaS:Eu²⁺; CaS:Eu²⁺,Mn²⁺; (Zn,Cd)S:Ag⁺; Mg₄GeO_{5.5}F:Mn⁴⁺; Y₂ O₂S:Eu²⁺, ZnS:Mn²⁺, CaAlSiN₃:Eu for red emission, and further phosphor materials having emission spectra in the red region of the visible spectrum upon excitation as described herein. For green emission, typical phosphor particles that are also suitable for use in the phosphor composition comprise a material selected from (Ba,Sr)₂SiO₄:Eu²⁺, SrGa₂S₄:Eu²⁺; ZnS:Cu, Al and other phosphor materials having emission spectra in the green region of the visible spectrum upon excitation as described herein. In certain embodiment, blue emitting phosphor particles may be included in the phosphor composition in addition to the red- and green-emitting phosphors; suitable blue emitting phosphor particles may comprise, e.g. BaMg₂Al₁₆O₂₇:Eu²⁺, Mg or other phosphor materials having emission spectra in the blue region of the visible spectrum upon excitation as described herein. In another embodiment, the phosphor composition comprises a type of phosphor particles that is selected to produce yellow light upon excitation. For yellow emission, typical phosphor particles suitable for use in the phosphor composition comprise a material selected from (Y,Gd)₃ Al₅O₁₂:Ce,Pr and other phosphor materials having emission spectra in the yellow region of the visible spectrum upon excitation as described herein.

Although the present invention is illustrated in connection with specific embodiments for instructional purposes, the present invention is not limited thereto. Various adaptations and modifications may be made without departing from the scope of the invention. For example, the composite luminescence converters may be manufactured from phosphor materials other than the phosphors cited. Any conventional phosphor material may be used in place of these phosphors. Therefore, the spirit and scope of the appended claims should not be limited to the foregoing description.

### BRIEF DESCRIPTION OF THE DRAWINGS

FIG. 1 shows a schematic side view of ac white LED lamp comprising a composite ceramic luminescence converter of the present invention positioned in the pathway of light emitted by an light-emitting diode flip chip structure.

FIG. 2 shows the emission spectrum of a ceramic luminescence converter according to a specific embodiment.

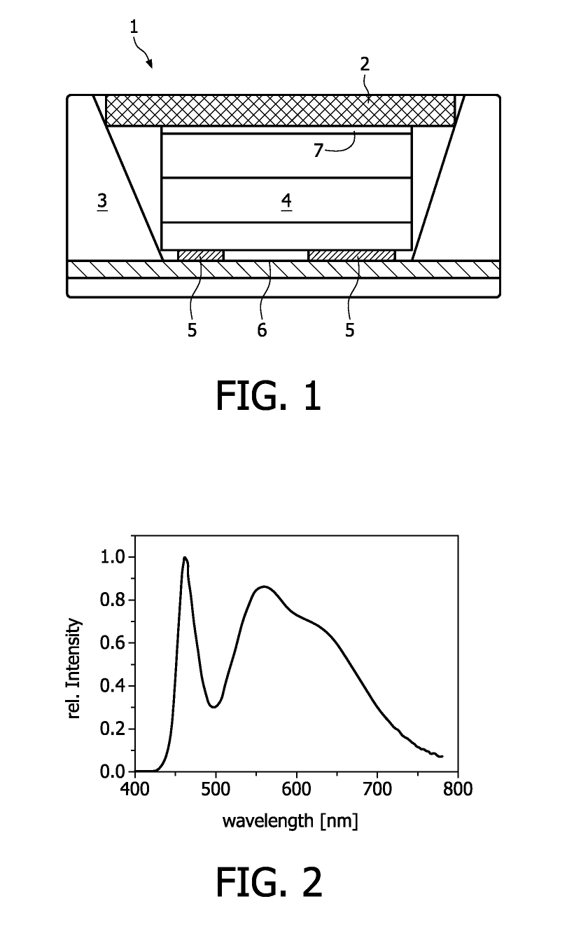

1. An illumination system comprising a radiation source and a composite monolithic ceramic luminescence converter comprising a composite luminescent material comprising at least one first phosphor and at least one second phosphor capable of absorbing a part of the light emitted by the radiation source and emitting light of a wavelength different from that of the absorbed light.

2. An illumination source according to claim 1, wherein the radiation source is a light emitting diode.

3. An illumination system according to claim 1, wherein the composite luminescent material is a particle-particle composite.

4. An illumination system according to claim 1, wherein the composite luminescent material is a stacked multilayer composite.

5. An illumination system according to claim 1, wherein the first phosphor is a green-emitting phosphor and the second phosphor is a red-emitting phosphor.

6. An illumination system according to claim 5, wherein the green phosphor is an europium(II)-doped alkaline earth oxonitridosilicate phosphor of general formula AeSi₂N₂O₂:Eu and the red phosphor is an europium(II)-doped alkaline earth nitridosilicate phosphor of general formula Ae₂Si₅N₈:Eu.

7. An illumination system according to claim 1, wherein the first phosphor is a yellow-emitting phosphor and the second phosphor is a blue-emitting phosphor.

8. A composite monolithic ceramic luminescence converter comprising composite luminescent material comprising at least one first phosphor and at least one second phosphor capable of absorbing a part of the light emitted by the radiation source and emitting light of a wavelength different from that of the absorbed light.

9. A method of manufacturing a composite monolithic ceramic luminescence converter comprising a composite luminescent material comprising at least one first phosphor and at least one second phosphor capable of absorbing a part of the light emitted by the radiation source and emitting light of a wavelength different from that of the absorbed light by
(i) preparing a powder mixture, mixing a precursor of a first phosphor material with a second material, that is selected from the group of a second phosphor material and a precursor of the second phosphor material, (ii) compacting and shaping the powder mixture into a preform, and (iii) co-sintering the preformed mixture.

10. A method according to claim 9, wherein the precursor material is a green (non-sintered) ceramic phosphor powder.

11. A method according to claim 9, wherein the first phosphor is a green-emitting europium(II)-doped alkaline earth oxonitridosilicate phosphor of general formula AeSi₂N₂O₂:Eu and the second phosphor is a red-emitting europium(II)-doped alkaline earth nitridosilicate phosphor of general formula Ae₂Si₅N₈:Eu, wherein the precursor of the first phosphor and the precursor of the second phosphor comprise a mixed oxide of an alkaline earth metal AeO:Eu and europium and silicon nitride Si₃N₄.
